(19) United States
(12) Patent Application Publication
(10) Pub. No.: US 2025/0258225 A1
(43) Pub. Date: Aug. 14, 2025

(54) TEST CIRCUIT AND INTEGRATED CIRCUIT INCLUDING THE SAME

(71) Applicant: SAMSUNG ELECTRONICS CO., LTD., SUWON-SI (KR)

(72) Inventors: Sangsoon Im, Suwon-sI (KR); Dongsu Lee, Suwon-sI (KR)

(21) Appl. No.: 18/969,521

(22) Filed: Dec. 5, 2024

(30) Foreign Application Priority Data
Feb. 8, 2024 (KR) 10-2024-0019837
Apr. 12, 2024 (KR) 10-2024-0049409

(51) Int. Cl. G01R 31/319; H03K 17/00; H03K 19/20

(52) U.S. Cl. CPC G01R 31/31915; H03K 17/005; H03K 19/20

(57) ABSTRACT

A test circuit includes a first input multiplexer configured to receive a first input data signal and a second input data signal, a second input multiplexer configured to receive a first output signal and a third input data signal of the first input multiplexer, a third input multiplexer configured to receive a second output signal and a fourth input data signal of the second input multiplexer, a test block configured to generate an output data signal by performing a test operation based on an output of the third input multiplexer, and a gating circuit configured to receive the output data signal and output the received output data signal to at least one channel.

### CROSS-REFERENCE TO RELATED APPLICATIONS

This application claims priority under 35 U.S.C. § 119 to Korean Patent Application Nos. 10-2024-0019837, filed on Feb. 8, 2024, and 10-2024-0049409, filed on Apr. 12, 2024, in the Korean Intellectual Property Office, the disclosures of which are herein incorporated by reference in their entirety.

### BACKGROUND

### 1. Technical Field

The inventive concept relates to a test circuit and an integrated circuit including the same, and more particularly, to a test circuit and an integrated circuit implementing a test structure.

### 2. Discussion of Related Art

As semiconductor technology continues to be developed, levels of performance and integration of integrated circuits are increasing. Accordingly, semiconductor testing technology to ensure the quality of semiconductor chips and improve testing efficiency is becoming increasingly important. Design For Test (DFT) technology is widely used, and among DFT technologies, scan test technology holds a significant position.

However, when performing scan tests on semiconductor devices, problems such as decreased accuracy of test results and increased costs for testing are occurring as the integration of the integrated circuits increases.

### SUMMARY

The inventive concept provides a test circuit and an integrated circuit that support a flexible test structure.

According to an aspect of the inventive concept, there is provided a test circuit including a first input multiplexer configured to receive a first input data signal and a second input data signal, a second input multiplexer configured to receive a first output signal and a third input data signal of the first input multiplexer, a third input multiplexer configured to receive a second output signal and a fourth input data signal of the second input multiplexer, a test block configured to generate an output data signal by performing a test operation based on an output of the third input multiplexer, and a gating circuit configured to receive the output data signal and output the received output data signal to at least one channel.

According to another aspect of the inventive concept, there is provided a test circuit including a first input multiplexer configured to select one of a first input data signal and a first input enable signal, a second input multiplexer configured to select one of a second input data signal and a second input enable signal, a third input multiplexer configured to select one of a third input data signal and a third input enable signal, and a fourth input multiplexer configured to select one of a fourth input data signal and a fourth input enable signal, a test block configured to generate an output data signal by performing a test operation based on the selections of the first input multiplexer, the second input multiplexer, the third input multiplexer, and the fourth input multiplexer, and a gating circuit configured to receive the output data signal and output the received output data signal to at least one channel.

According to another aspect of the inventive concept, there is provided an integrated circuit including a plurality of channels, at least one intellectual property (IP) block, an input gating circuit including a plurality of input terminals including a first input terminal, each input terminal of the plurality of input terminals connected to a different channel among the plurality of channels, and configured to output a signal received through the first input terminal as an input data signal, a test block configured to generate an output data signal by testing the at least one IP block based on the input data signal, and an output gating circuit including a plurality of output terminals including a first output terminal, each output terminal of the plurality of output terminals connected to a different channel among the plurality of channels, and configured to output the output data signal through the first output terminal.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating an integrated circuit according to an embodiment;

FIG. 2 is a block diagram illustrating an example of a test core according to an embodiment;

FIG. 3A and FIG. 3B are diagrams to explain a sequential logic circuit included in a scan chain circuit according to an embodiment;

FIG. 4 is a diagram illustrating an example of an integrated circuit according to an embodiment;

FIG. 5 is a diagram illustrating an example of a test circuit according to an embodiment;

FIG. 6 is a circuit diagram showing a gating circuit according to an embodiment;

FIG. 7 is a diagram illustrating an example of a test circuit according to an embodiment;

FIG. 8 is a circuit diagram showing a gating circuit according to an embodiment;

FIG. 9 is a diagram illustrating an example of an integrated circuit according to an embodiment;

FIG. 10A and FIG. 10B are diagrams showing changes in input terminals according to an embodiment;

FIG. 11A and FIG. 11B are diagrams showing changes in output terminals according to an embodiment;

FIG. 12 illustrates a system including an integrated circuit according to an embodiment; and

FIG. 13 is a block diagram showing an example of applying an integrated circuit according to embodiments to a solid state device (SSD) system.

### DETAILED DESCRIPTION

Hereinafter, embodiments of the inventive concept are described in detail with reference to the attached drawings. The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

Like reference numerals or symbols refer to like elements throughout. In the drawings, the thicknesses, the ratios, and the dimensions of the elements may be exaggerated for effective description of the technical contents.

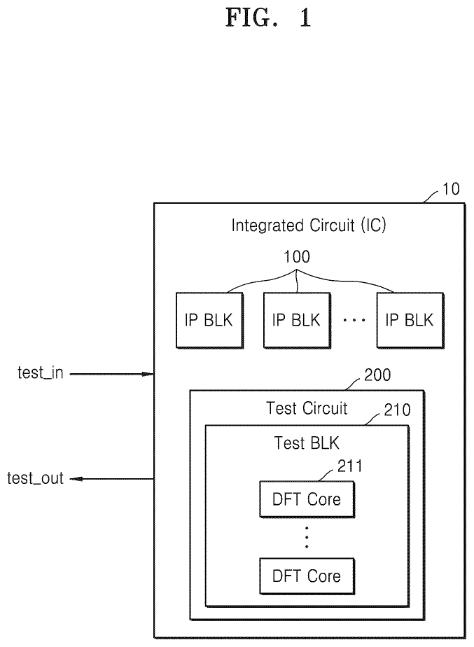

FIG. 1 is a block diagram illustrating an integrated circuit according to an embodiment.

Referring to FIG. 1, an integrated circuit 10 may include a plurality of intellectual property (IP) blocks 100 and a test circuit 200. The plurality of IP blocks 100 may include various core blocks and/or logic circuits. The IP blocks 100 may perform various functions of the integrated circuit 10. FIG. 1 illustrates that the integrated circuit 10 includes a test circuit 200, but this is an example, and the integrated circuit 10 may include more test circuits, which may be used to test multiple IP blocks 100. In an embodiment, the integrated circuit 10 may be implemented as a system on-chip (SoC).

The test circuit 200 may include a test block 210. The test block 210 may include one or more test cores. The test cores may be used for performing a test operation. An example of a test core may include a Design For Test (DFT) core 211. The test circuit 200 may be a circuit for testing multiple IP blocks 100. As an example, the test circuit 200 may be a circuit for testing for a defect in the integrated circuit 10. For example, the test circuit 200 may test for defects in multiple IP blocks 100 of the integrated circuit 10 using the test block 210. In an embodiment, the test circuit 200 may perform the test operation to check whether each IP block of a plurality of IP blocks 100 function normally and/or satisfy timing conditions.

The test circuit 200 may perform a test operation based on a test signal received by the integrated circuit 10. The test signal received by the integrated circuit 10 may be a test input signal test_in. The test circuit 200 may receive the test input signal test_in and may test one or more IP blocks corresponding to the test input signal test_in among a plurality of IP blocks 100 using the test block 210. The test circuit 200 may output a test output signal test_out, which may be a test result for the one or more IP blocks. In an embodiment, the integrated circuit 10 may receive the test input signal test_in from test equipment and may transmit the received test input signal test_in to the test circuit 200. The integrated circuit 10 may provide the test output signal test_out from the test circuit 200 to the test equipment. In some embodiments, the test equipment may be referred to as Automated Test Equipment (ATE). The test circuit 200 may include input/output terminals (or ports or pads) for transmitting and receiving signals, which may be related to testing.

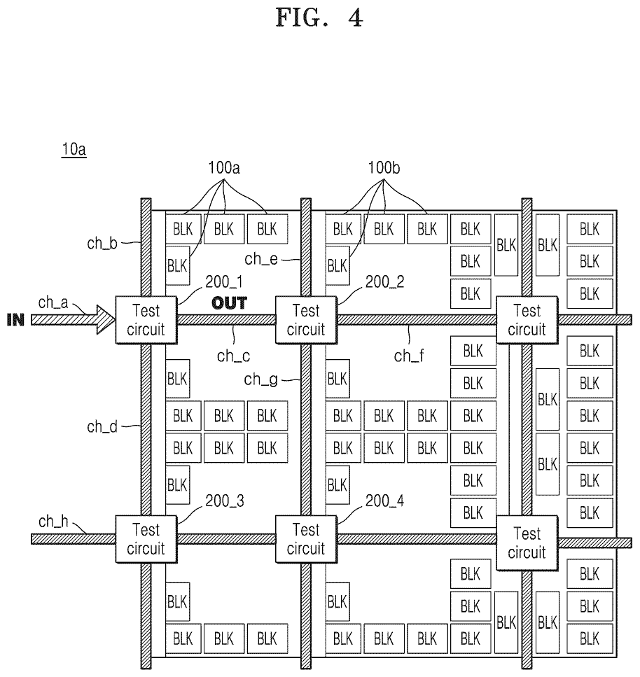

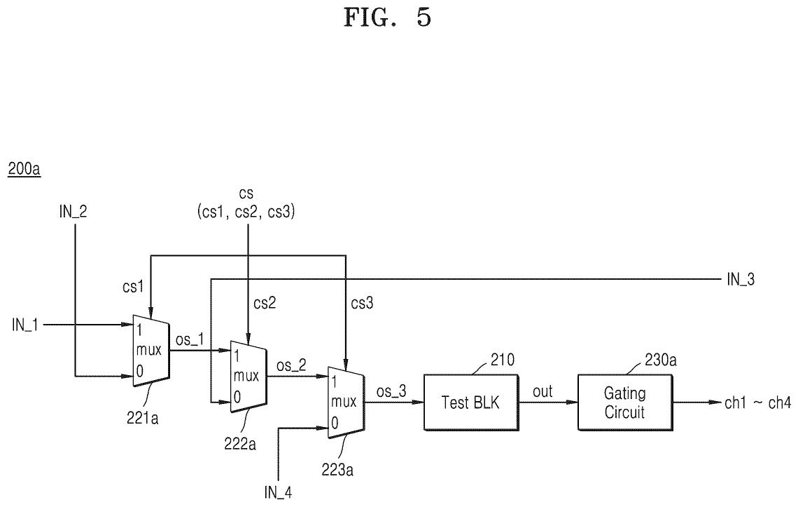

In some embodiments, when the integrated circuit 10 includes a plurality of test circuits, the test circuit 200 may output an output data signal to another test circuit. The output data signal may be a test result for a corresponding IP block. A detailed explanation is provided herein with reference to FIG. 4. In some embodiments, the test circuit 200 may further include circuits for input/output operations in addition to the test block 210, which may transmit and receive signals to and from other test circuits. A detailed explanation is provided herein with reference to FIGS. 5 to 8.

The test input signal test_in may include a scan input signal, a scan enable signal, and a test control signal. In this case, the test control signal may include a signal for controlling the input/output circuit. In some embodiments, the test control signal may include a control signal for controlling multiplexers depending on an operating mode, and may also include a signal for controlling a gating circuit for gating the signal. In some embodiments, the test control signal may include an input enable signal and/or an output enable signal for setting up a test path. In some embodiments, the test control signal may be a signal for controlling the input terminal and/or the output terminal, or for controlling multiplexers connected thereto.

In some embodiments, the scan input signal may include test pattern data (or test pattern) for testing the plurality of IP blocks 100 included in the integrated circuit 10. The test pattern data may refer to data input into an integrated circuit 10 through the test equipment. The test pattern data may be values arbitrarily entered by a user operating the test equipment, or may be data previously entered into the test equipment.

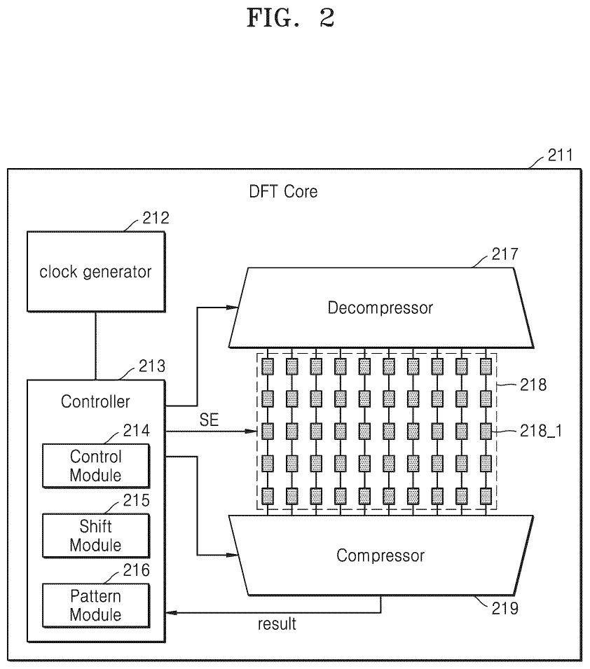

FIG. 2 is a block diagram illustrating an example of a test core according to an embodiment.

FIG. 2 illustrates a DFT core 211, which is an example of a test core including a plurality of scan chains 218. The DFT core 211 may include a clock generator 212, a controller 213, a decompressor 217, the plurality of scan chains 218, and a compressor 219.

The clock generator 212 may receive, for example, a shift clock and an operation clock, and generate various clocks for the test operation under the control of the controller 213.

The controller 213 may control an operation of the DFT core 211. The controller 213 may include a control module 214, a shift module 215, and a pattern module 216. In some embodiments, the control module 214 may generate a scan enable signal SE. The scan enable signal SE may correspond to a test pattern. The plurality of scan chains 218 may perform a normal operation or a scan shift operation based on the scan enable signal SE. The normal operation may be referred to as capture operation. The shift module 215 may be a module for performing a shift operation of flip-flops included in each of the plurality of scan chains 218. The pattern module 216 may be a module for controlling the test pattern.

The decompressor 217 may include a pseudo random pattern generator (PRPG). The PRPG may be composed of a linear feedback shift register (LFSR). The PRPG may include a phase shifter.

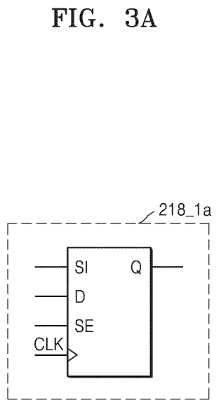

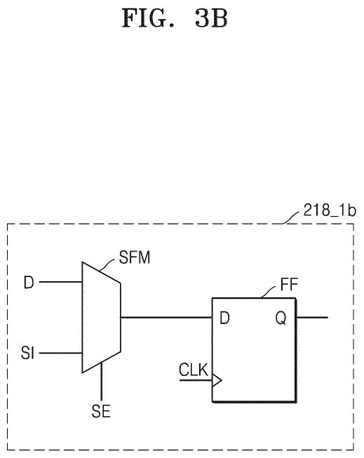

The plurality of scan chains 218 may include a plurality of sequential logic circuits. Here, the sequential logic circuit may be a circuit including a memory element. The sequential logic circuit may be a circuit that may output different output data depending on a memory state. The sequential logic circuit may output different output data depending on a memory state even if the same input data is input. Additionally, the plurality of sequential logic circuits may be a plurality of sequential logic circuits connected in series with each other. The sequential logic circuits may include scan flip-flops. A scan flip-flop is described with reference to FIG. 3A and FIG. 3B.

Each scan chain may proceed with a process of latching scan data transmitted from the decompressor 217 into flip-flops in response to a scan enable signal SE generated by a controller 213, capturing the result data that passed through the logic circuit connected to the scan chain, and outputting the captured data to the compressor 219 based on the test pattern. The compressor 219 may include a compactor that may compact data output from the plurality of scan chains 218 and a comparator, and may generate a test result.

The DFT core 211 may further include various configurations for performing test operations in addition to the configurations illustrated in the drawing.

FIG. 3A and FIG. 3B are diagrams to explain a sequential logic circuit included in a scan chain circuit according to an embodiment. FIG. 3A and FIG. 3B may illustrate examples of scan flip-flop 218_1 included in the plurality of scan chains 218 of FIG. 2, and the description already given may be omitted or simplified.

Referring to FIG. 3A, a first scan flip-flop 218_1a may receive a data signal D, a scan input signal SI, or a scan enable signal SE, and may output an output signal Q depending on a clock signal CLK. The scan enable signal SE provided to the first scan flip-flop 218_1a may be provided from the controller 213 included in the DFT core 211 or from the test equipment.

The scan enable signal SE may indicate the normal operation (or capture operation) or the scan shift operation depending on the logic level. When the scan enable signal SE indicates the normal operation, the first scan flip-flop 218_1a may perform the normal operation of storing the data signal D and providing the stored value as an output signal Q. When the scan enable signal SE indicates the scan shift operation, the first scan flip-flop 218_1a may perform the scan shift operation that stores a scan input signal SI and provides the stored value as an output signal Q.

Referring to FIG. 3A, a second scan flip-flop 218_1b may include a multiplexer SFM and a flip-flop FF. The multiplexer SFM may output a data signal D or a scan input signal SI to the flip-flop FF depending on the logic level of the scan enable signal SE. For example, when the scan enable signal SE indicates the normal operation, the data signal D may be output to the flip-flop FF. Additionally, when the scan enable signal SE indicates the scan shift operation, the scan input signal SI may be output to the flip-flop FF. The second scan flip-flop 218_1b may store the output value of the multiplexer SFM depending on the clock signal CLK and output the stored value as an output signal Q.

FIG. 4 is a diagram illustrating an example of an integrated circuit according to an embodiment. An integrated circuit 10a of FIG. 4 may be an example of the integrated circuit 10 of FIG. 1.

Referring to FIG. 1 and FIG. 4, the integrated circuit 10a may include a plurality of IP blocks, for example, first IP blocks 100a, a first test circuit 200_1, a second test circuit 200_2, a third test circuit 200_3, and a fourth test circuit 200_4. The plurality of IP blocks may correspond to the plurality of IP blocks 100 of FIG. 1, and the first to fourth test circuits 200_1, 200_2, 200_3, and 200_4 may correspond to the test circuit 200 of FIG. 1. FIG. 4 may be described with reference to FIG. 1, and descriptions already given may be omitted or simplified.

The first test circuit 200_1 may be a test circuit corresponding to the first IP blocks 100a, and the second test circuit 200_2 may be a test circuit corresponding to second IP blocks 100b. The first test circuit 200_1 may receive a test signal and perform a test operation on the first IP blocks 100a.

The first test circuit 200_1 may perform a test operation by receiving an input data signal IN through a channel ch_a (or bus) and may generate an output data signal, which may be a test result. As an example, the input data signal IN may be a signal corresponding to the test input signal test_in of FIG. 1. That is, the input data signal IN may be a test signal received by the integrated circuit 10a from an external source such as test equipment. As another example, the input data signal IN may be a test result received from an adjacent test circuit, for example, an output data signal of the adjacent test circuit. For example, as illustrated, the first test circuit 200_1 may receive an output data signal of an adjacent test circuit as an input data signal IN through the channel ch_a. However, without being limited, the first test circuit 200_1 may also receive the input data signal IN through channels ch_b, ch_c, or ch_d. That is, the direction in which the first test circuit 200_1 receives the input data signal IN to perform a test may be implemented in various ways depending on the configuration and/or structure of the channels connected to the first test circuit 200_1.

In some embodiments, the first test circuit 200_1 may perform the test operation based on an input data signal IN, generate an output data signal OUT, and output the output data signal OUT through one or more of channels ch_a, ch_b, ch_c, or ch_d. That is, the direction in which the output data signal OUT generated by the first test circuit 200_1 is output may be implemented in various ways depending on the configuration and/or structure of the channels connected to the first test circuit 200_1.

In some embodiments, the first test circuit 200_1 may output an output data signal OUT to any one of the channels ch_a, ch_b, ch_c, or ch_d. As an example, the first test circuit 200_1 may output the generated output data signal OUT to the channel ch_c, and the second test circuit 200_2 may receive the output data signal OUT as an input data signal through the channel ch_c, and the second test circuit 200_2 may perform a test operation on the second IP blocks 100b. Similarly, the second test circuit 200_2 may receive the output data signal OUT as an input data signal IN, perform a test operation, and generate an output data signal to output through one or more of channels ch_c, ch_e, ch_f, or ch_g. That is, the direction in which the output data signal generated by the second test circuit 200_2 is output may also be implemented in various ways depending on the configuration and/or structure of the channels connected to the second test circuit 200_2. In other words, the input/output directions of the test circuits may be flexibly set.

As another example, the first test circuit 200_1 may output the generated output data signal OUT to the channel ch_d, and the third test circuit 200_3 may receive the output data signal OUT as an input data signal through the channel ch_d and perform a test on IP blocks corresponding to the third test circuit 200_3. The third test circuit 200_3 may transmit an output data signal to the fourth test circuit 200_4, and the fourth test circuit 200_4 may provide an output data signal generated by performing a test to the second test circuit 200_2 through the channel ch_g.

In this way, the test path may be set to the first test circuit 200_1 and the second test circuit 200_2, or may be set to the first test circuit 200_1, the third test circuit 200_3, the fourth test circuit 200_4, and the second test circuit 200_2. That is, based on the flexible input/output structure of the test circuits as described herein, the test path may be set in various ways.

As another example, the first test circuit 200_1 may provide the generated output data signal OUT to the third test circuit 200_3 through the channel ch_d, and the third test circuit 200_3 may perform a test and output the generated output data signal through the channel ch_h. The signal output through the channel ch_h may correspond to the test result signal test_out of FIG. 1, or in other words, may be the result of a test for the integrated circuit 10a. That is, the test path may be set so that tests are not performed on the second test circuit 200_2 and the fourth test circuit 200_4. In other words, when a test result for the first test circuit 200_1 or the third test circuit 200_3 is to be obtained, the test path may be set to a shortest path so that at least some test operations of other test circuits may not be performed. The shortest path may bypass at least some test operations of the other test circuits, which may not be related to obtaining the test result for the first test circuit 200_1 or the third test circuit 200_3.

Referring again to FIG. 4, the input/output directions of the test circuits are depicted in four directions: up, down, left, and right, but the inventive concept is not limited thereto. That is, the input/output direction may be implemented in various ways depending on the structure and configuration of the channels (or buses) connected to the test circuits. Hereinafter, for convenience of explanation, the input/output directions of the test circuit according to an embodiment are illustrated and described as four directions.

In this way, the integrated circuit according to an embodiment may support a flexible test architecture that may set up a variety of test paths and test progress directions depending on the purpose and situation by configuring the input/output directions of the test circuits (or test cores) in various ways. For example, the direction of test progress is not limited to one direction and may be set in various directions.

In addition, when the target test circuit (or test core) to be tested is specified, the cost and time consumed for testing may be reduced by setting the path so that the test operations of other test circuits may not be performed. For example, test operations of other test circuits not related to the target test circuit (or test core) to be tested may not be performed. Additionally, intensive testing of specific IP blocks based on various test patterns may also be performed more efficiently.

Furthermore, the integrated circuit according to an embodiment may also detect defects in channels between test circuits by changing the test path. For example, in cases where test results are not output normally due to defects in the test channel despite normal operation of IP blocks, by performing tests by changing the test path, it may be possible to avoid a situation in which a normally operating chip is determined to be defective, which may be considered a false-positive result. Therefore, the integrated circuit according to an embodiment may increase the yield of the chip and improve the test analysis capability. Defects in the test channel may have various causes. For example, defects in the test channel may include a timing requirement failure, contamination by material, a short, an open, or noise. Embodiments are not limited to example defects.

FIG. 5 is a diagram illustrating an example of a test circuit according to an embodiment. A test circuit 200a of FIG. 5 may correspond to the test circuit 200 of FIG. 1 or the test circuits 200_1, 200_2, 200_3, and 200_4 of FIG. 4.

Referring to FIG. 1, FIG. 4, and FIG. 5, the test circuit 200a may include a plurality of input multiplexers, a test block 210, and a gating circuit 230a. The plurality of input multiplexers may include, for example, a first input multiplexer 221a, a second input multiplexer 222a, and a third input multiplexer 223a. The test circuit 200a may include the plurality of input multiplexers 221a, 222a, and 223a to selectively receive input data signals from adjacent test circuits. A first input data signal IN_1, a second input data signal IN_2, a third input data signal IN_3, and a fourth input data signal IN_4 may be output data signals that may be test results of adjacent test circuits, or may be test signals received from the outside.

In some embodiments, the first input multiplexer 221a may receive a first input data signal IN_1 and a second input data signal IN_2. The first input multiplexer 221a may select a signal from among the first input data signal IN_1 and a second input data signal IN_2 and output the selected signal as a first output signal os_1. The second input multiplexer 222a may receive the first output signal os_1 and the third input data signal IN_3, and may select a signal from among the first output signal os_1 and the third input data signal IN_3 to output the selected signal as a second output signal os_2. Similarly, the third input multiplexer 223a may select a signal from among the second output signal os_2 and the fourth input data signal IN_4 and provide the selected signal to the test block 210 as a third output signal os_3. The test block 210 may perform a test operation based on a signal selected through one or more multiplexing operations.

That is, the test circuit 200a according to an embodiment may perform a test operation based on any one of the input data signals IN_1, IN_2, IN_3, or IN_4 that are outputs of adjacent test circuits. In other words, the direction in which the test circuit 200a receives the input data signal may be flexible and may be implemented in various ways.

In some embodiments, the plurality of input multiplexers 221a, 222a, and 223a may perform a multiplexing operation based on a control signal cs. The control signal cs may be a signal provided externally. For example, the control signal cs may be a signal provided from test equipment or a test network within the integrated circuit 10. The control signal cs may control an operation mode of the test circuit 200a. A number of operation modes of the test circuit 200a may defined to test the test block 210 using an input data signal received through different channels. The control signal cs may be used to selection an operation from among the number of operation modes. The control signal cs may include a first control signal cs1, a second control signal cs2, and a third control signal cs3. The control signal cs may be configured in various ways depending on the operation mode. The first input multiplexer 221a may select a signal based on the first control signal cs1, the second input multiplexer 222a may select a signal based on the second control signal cs2, and the third input multiplexer 223a may select a signal based on the third control signal cs3.

In an embodiment, in the first operation mode, the test circuit 200a may receive the control signal cs that is set to use the first input data signal IN_1 for the test operation. In detail, for example, the first control signal cs1 may be set to a first value, which is a logic high level, and thus the first input multiplexer 221a may select the first input data signal IN_1 as the first output signal os_1. The second control signal cs2 may be set to a first value, which is a logic high level, and the second input multiplexer 222a may select the first output signal os_1 as the second output signal os_2. In a similar manner, the third control signal cs3 may be set to the first value, and thus the test block 210 may receive the first input data signal IN_1.

In another embodiment, in the second operation mode, the test circuit 200a may receive a control signal cs that is set to use the second input data signal IN_2 for the test operation. For example, the first control signal cs1 may be set to a second value, which is a logic low level, and the first input multiplexer 221a may select the second input data signal IN_2 as the first output signal os_1. The second control signal cs2 and the third control signal cs3 may be set to the first value, and the test block 210 may receive the second input data signal IN_2.

In the third operation mode, the second control signal cs2 is set to the second value, the third control signal cs3 is set to the first value, and the test block 210 may receive the third input data signal IN_3. In the fourth operation mode, the third control signal cs3 is set to the second value so that the test block 210 may receive the fourth input data signal IN_4. However, it is to be understood that, without being limited, the first value may refer to a logic low level, the second value may refer to a logic high level, and the configuration and/or structure of the multiplexers may be implemented to correspond thereto.

The test block 210 may receive an input data signal selected through a multiplexing process as described herein, perform a test, and generate an output data signal out indicating the test result and transmit the generated output data signal out to the gating circuit 230a.

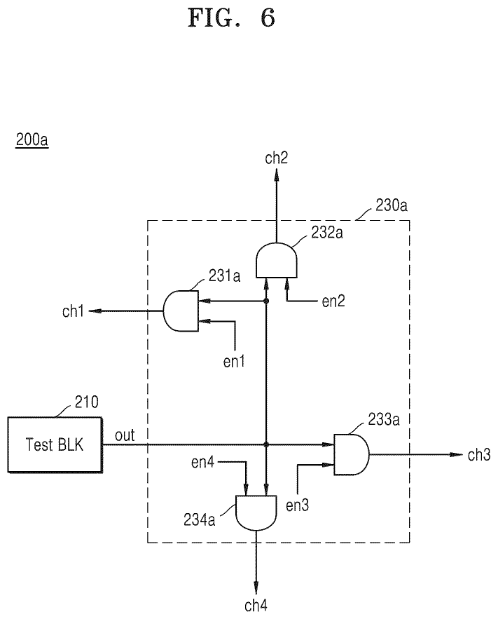

In some embodiments, the gating circuit 230a may output an output data signal out received through a gating operation to at least one of a plurality of channels ch1 to ch4. A detailed description of the gating circuit 230a is provided with reference to FIG. 6.

That is, the test circuit 200a according to an embodiment may select which of the signals provided from multiple directions (or provided from adjacent test circuits) to provide to the test block 210 based on a control signal. The test circuit 200a may select which of the signals provided from multiple directions (or provided from adjacent test circuits) to provide to the test block 210 based on a control signal, enabling a flexible test structure.

FIG. 6 is a circuit diagram showing a gating circuit according to an embodiment.

Referring to FIG. 5 and FIG. 6, a gating circuit 230a may a plurality of logic gates. For example, the gating circuit 230a may include a first AND gate 231a, a second AND gate 232a, a third AND gate 233a, and a fourth AND gate 234a that receive an output data signal out. The gating circuit 230a may selectively transmit the output data signal out to channels ch1, ch2, ch3, and ch4 through a plurality of AND gates, for example, the first AND gate 231a, the second AND gate 232a, the third AND gate 233a, and the fourth AND gate 234a.

In some embodiments, the plurality of AND gates 231a, 232a, 233a, and 234a may perform a gating operation based on a plurality of enable signals en1, en2, en3, and en4. The plurality of enable signals en1, en2, en3, and en4 may be signals provided externally (e.g., from test equipment or a test network within the integrated circuit 10).

In an embodiment, the first AND gate 231a may correspond to a first channel ch1 and receive the first enable signal en1. The second AND gate 232a may correspond to a second channel ch2 and receive the second enable signal en2. The third AND gate 233a may correspond to a third channel ch3 and receive the third enable signal en3. The fourth AND gate 234a may correspond to a fourth channel ch4 and receive the fourth enable signal en4. For example, when the first enable signal en1 is an activated signal (e.g., a signal having a logic high level), the output data signal out may be output to the first channel ch1. On the other hand, when the first enable signal en1 is a disabled signal (e.g., a signal having a logic low level), the output to the first channel ch1 may be blocked. In the same manner, the second AND gate 232a to the fourth AND gate 234a may perform a gating operation based on the enable signal received by each of the second AND gate 232a to the fourth AND gate 234a.

In some embodiments, only one of the multiple enable signals en1, en2, en3, and en4 may be an activated signal. That is, the gating circuit 230a may output the output data signal out to only one of the channels ch1, ch2, ch3, and ch4 based on the plurality of received enable signals en1, en2, en3, and en4.

That is, the test circuit 200a according to an embodiment may select in which direction (or to which test circuit) to provide the output of the test circuit 200a based on the enable signal. The test circuit 200a according to an embodiment may select in which direction (or to which test circuit) to provide the output of the test circuit 200a based on the enable signal having a flexible test structure.

In addition, the test circuit 200a according to an embodiment may reduce a number of toggles while transmitting scan data by activating the channels included in the test path among the plurality of channels and deactivating remaining channels. The test circuit 200a, which may reduce a number of toggles, may reduce power consumption. For example, the test circuit 200a activate only the channels including in the test path, which may reduce the number of toggles while transmitting scan data.

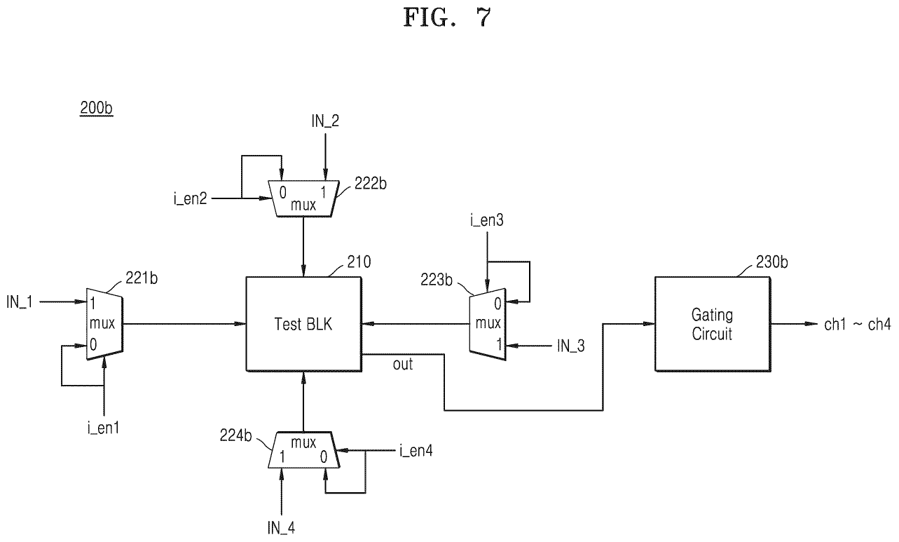

FIG. 7 is a diagram illustrating an example of a test circuit according to an embodiment. A test circuit 200b of FIG. 7 may correspond to the test circuit 200 of FIG. 1 or the test circuits 200_1, 200_2, 200_3, and 200_4 of FIG. 4.

Referring to FIG. 1, FIG. 4, and FIG. 7, the test circuit 200b may include a plurality of input multiplexers, a test block 210, and a gating circuit 230b. The plurality of input multiplexers may include, for example, a first input multiplexer 221b, a second input multiplexer 222b, a third input multiplexer 223b, and a fourth input multiplexer 224b. The test circuit 200b may include the plurality of input multiplexers 221b, 222b, 223b, and 224b to selectively receive input data signals. For example, the test circuit 200b may include the plurality of input multiplexers 221b, 222b, 223b, and 224b to selectively gate the input data signals. A plurality of input data signals IN_1, IN_2, IN_3, and IN_4 received through each channel may be output data signals that include test results of adjacent test circuits, or may be test signals received from the outside.

In an embodiment, the first input multiplexer 221b may receive the first input data signal IN_1 and a first input enable signal i_en1. The second input multiplexer 222b may receive the second input data signal IN_2 and a second input enable signal i_en2. The third input multiplexer 223b may receive the third input data signal IN_3 and a third input enable signal i_en3. The fourth input multiplexer 224b may receive the fourth input data signal IN_4 and a fourth input enable signal i_en4.

In some embodiments, each of the plurality of input multiplexers 221b, 222b, 223b, and 224b may perform a multiplexing operation based on the corresponding plurality of input enable signals i_en1, i_en2, i_en3, and i_en4, and may select whether to provide a signal to the test block 210. The plurality of enable signals en1, en2, en3, and en4 may be signals provided from an external source. The external source may include test equipment or a test network within the integrated circuit 10. For example, when the first input enable signal i_en1 received by the first input multiplexer 221b is activated (e.g., at a logic high level), the first input data signal IN_1 may be provided to the test block 210. On the other hand, when the first input enable signal i_en1 is deactivated (e.g., at a logic low level), the output of the first input data signal IN_1 may be blocked. In a similar manner, the second input multiplexer 222b to the fourth input multiplexer 224b may perform a gating operation based on the input enable signal received by each of the second input multiplexer 222b to the fourth input multiplexer 224b.

In some embodiments, among a plurality of input enable signals i_en1, i_en2, i_en3, and i_en4, an input enable signal may be an activated signal. That is, the test circuit 200b may provide a signal selected from among the plurality of input data signals IN_1, IN_2, IN_3, and IN_4 to the test block 210 based on the plurality of received input enable signals i_en1, i_en2, i_en3, and i_en4.

The test block 210 may receive the input data signal selected through a multiplexing process as described herein, perform a test, and generate an output data signal out indicating the test result and transmit the generated output data signal out to the gating circuit 230b.

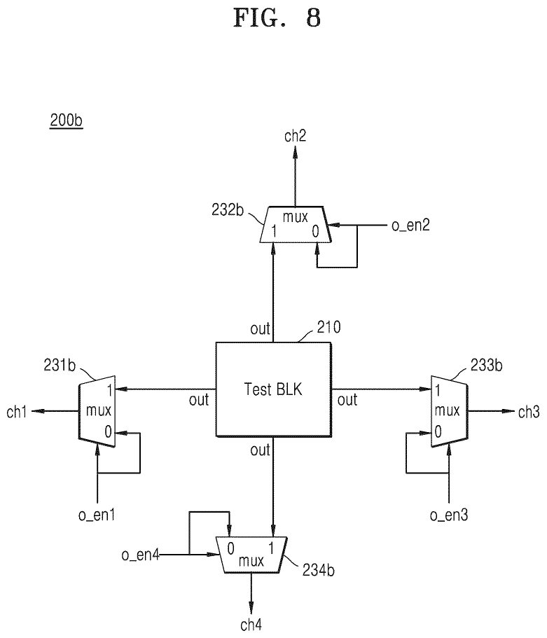

In some embodiments, the gating circuit 230b may output the output data signal out received through a gating operation to at least one of a plurality of channels ch1 to ch4. A detailed description of the gating circuit 230b is described with reference to FIG. 8.

That is, the test circuit 200b according to an embodiment may select whether to receive input data signal (or output test signal output from any of adjacent test circuits) provided from various directions based on the input enable signal. The test circuit 200b according to an embodiment may select whether to receive input data signal (or output test signal output from any of adjacent test circuits) provided from various directions based on the input enable signal may provide a flexible test structure.

In addition, the test circuit 200b according to an embodiment may prevent unnecessary toggling while transmitting scan data by activating only the channels included in the test path among a plurality of channels and deactivating the other channels, thereby reducing power consumption.

FIG. 8 is a circuit diagram showing a gating circuit according to an embodiment.

Referring to FIG. 7 and FIG. 8, a gating circuit 230b may include a plurality of output multiplexers, for example, a first output multiplexer 231b, a second output multiplexer 232b, a third output multiplexer 233b, and a fourth output multiplexer 234b that receive output data signals out. The gating circuit 230b may selectively transmit output data signals out to channels ch1, ch2, ch3, and ch4 through the plurality of output multiplexers, for example, the first output multiplexer 231b, the second output multiplexer 232b, the third output multiplexer 233b, and the fourth output multiplexer 234b.

In an embodiment, each of the first output multiplexer 231b to the fourth output multiplexer 234b may receive each of the first output enable signal o_en1 to the fourth output enable signal o_en4. In some embodiments, each of the plurality of output multiplexers 231b, 232b, 233b, and 234b may perform a multiplexing operation based on a corresponding plurality of output enable signals o_en1, o_en2, o_en3, and o_en4. The plurality of output enable signals o_en1, o_en2, o_en3, and o_en4 may be signals provided externally (e.g., from test equipment or a test network within the integrated circuit 10). For example, when the first output enable signal o_en1 is an activated signal (e.g., a signal having a logic high level), an output data signal out may be output to the first channel ch1. When the first output enable signal o_en1 is a disabled signal (e.g., a signal having a logic low level), the output to the first channel ch1 may be blocked. In the same manner, the second output multiplexer 232b to the fourth output multiplexer 234b may perform a gating operation based on the output enable signal received by each of the second output multiplexer 232b to the fourth output multiplexer 234b.

In some embodiments, a signal from among the multiple output enable signals o_en1, o_en2, o_en3, and o_en4 may be an activated signal. That is, the gating circuit 230b may output an output data signal out to a channel from among the channels ch1, ch2, ch3, and ch4 based on a plurality of received output enable signals o_en1, o_en2, o_en3, and o_en4.

That is, the test circuit 200b according to an embodiment may have a flexible test structure based on the output enable signal, and may reduce power consumption by reducing toggling by activating the channels included in the test path and deactivating other channels.

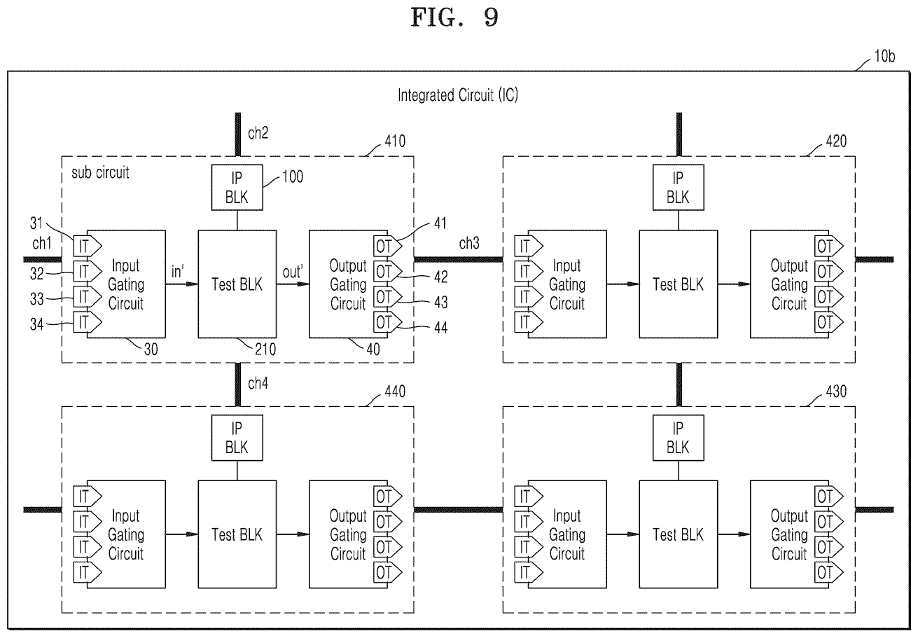

FIG. 9 is a diagram illustrating an example of an integrated circuit according to an embodiment. An integrated circuit 10b of FIG. 9 may be an example of the integrated circuit 10 of FIG. 1, or may correspond to the integrated circuit 10a of FIG. 4.

Referring to FIG. 1 and FIG. 9, the integrated circuit 10b may include a first sub-circuit 410, a second sub-circuit 420, a third sub-circuit 430, and a fourth sub-circuit 440. The first sub-circuit 410 may include an IP block 100, an input gating circuit 30, a test block 210, and an output gating circuit 40.

The input gating circuit 30 may be a circuit that selects an input terminal through the multiplexing operation as described with reference to FIG. 5 or FIG. 7 and receives a signal to be provided to the test block 210 as an input data signal in′. The output gating circuit 40 may be a circuit that selects an output terminal to which an output data signal out of the test block 210 is to be transmitted through the gating operation, as described with reference to FIG. 6 and FIG. 8. FIG. 9 may be described with reference to other drawings, and descriptions already given may be omitted or simplified.

The input gating circuit 30 may include a first input terminal 31, a second input terminal 32, a third input terminal 33, and a fourth input terminal 34. For example, each of the first input terminal 31 to the fourth input terminal 34 may be connected to a different channel among the first channel ch1 to the fourth channel ch4. The input gating circuit 30 may select which signal among the signals received from the first channel ch1 to the fourth channel ch4 to provide to the test block 210. The selected signal may be input to the test block 210 as an input data signal in' by selecting an input terminal through a series of gating operations (e.g., a signal selection operation through multiplexing).

In some embodiments, the input gating circuit 30 may perform a gating operation based on an input control signal provided from an external source (e.g., a test network within test equipment or an integrated circuit 10b). In an embodiment, the input control signal may be the control signal cs of FIG. 5 or the input enable signals i_en1 to i_en4 of FIG. 7. For example, the input gating circuit 30 may select a signal received through a channel connected to the first input terminal 31 as an input data signal in to be provided to the test block 210 based on an input control signal.

The output gating circuit 40 may include a first output terminal 41, a second output terminal 42, a third output terminal 43, and a fourth output terminal 44. For example, each of the first output terminal 41 to the fourth output terminal 44 may be connected to different channels among the first channel ch1 to the fourth channel ch4. The output gating circuit 40 may select which of the first channel ch1 to fourth channel ch4 the output data signal out is provided to by selecting an output terminal through a series of gating operations (e.g., a signal selection operation through an AND gate or a multiplexer).

In some embodiments, the output gating circuit 40 may perform a gating operation based on an output control signal provided from an external source (e.g., a test device or a test network within an integrated circuit 10b). In an embodiment, the output control signals may be the enable signals en_1 to en_4 of FIG. 6 or the output enable signals o_en1 to o_en4 of FIG. 8. For example, the output gating circuit 40 may output the output data signal out′ generated by the test block 210 to a channel connected to the third output terminal 43 based on the output control signal.

As an embodiment, the first input terminal 31 may be a terminal connected to the first channel ch1, and the input gating circuit 30 may select a signal received through the first channel ch1 as an input data signal in′. The third output terminal 43 may be a terminal connected to the third channel ch3, and the output gating circuit 40 may output the output data signal out to the third channel ch3.

The input gating circuit 30 may select an input terminal that is different from the first input terminal 31 based on the newly received input control signal, and may receive a signal transmitted through a channel different from the first channel ch1. In some embodiments, the output gating circuit 40 may select an output terminal that is different from the third output terminal 43 based on the newly received output control signal, and thus output a signal to a channel different from the third channel ch3. Therefore, test path settings between the first sub-circuit 410 to the fourth sub-circuit 440 may be flexibly made.

That is, the integrated circuit 10b according to an embodiment may change the input/output path of a signal in various ways by controlling the input gating circuit 30 and/or the output gating circuit 40, thereby having a flexible test structure.

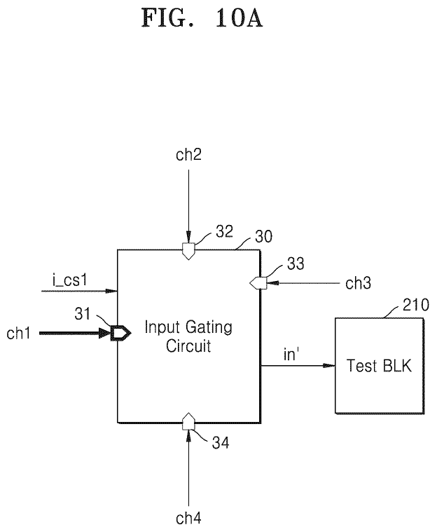

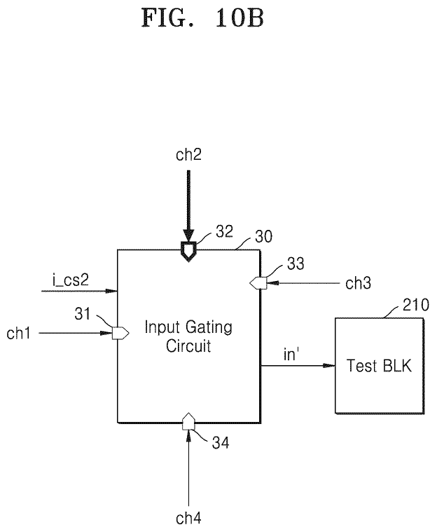

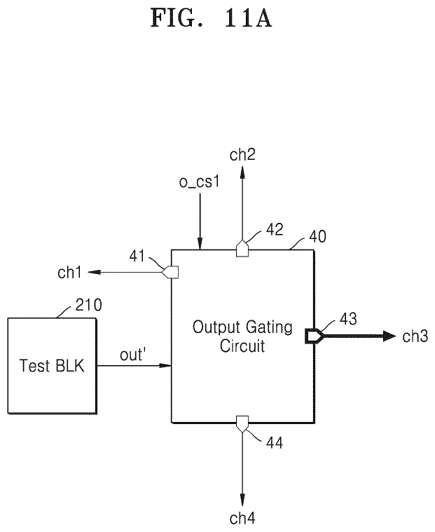

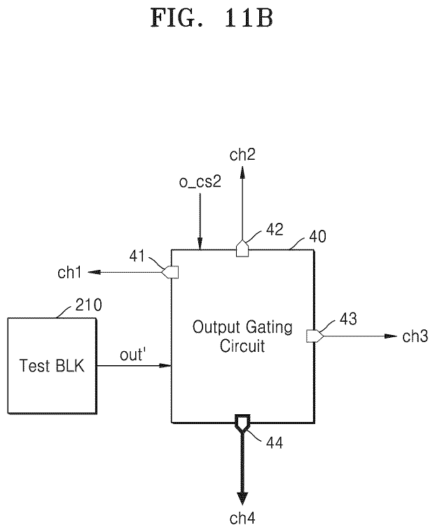

FIG. 10A and FIG. 10B are diagrams showing changes in input terminals according to an embodiment. FIG. 11A and FIG. 11B are diagrams showing changes in output terminals according to an embodiment

Referring to FIG. 9, FIG. 10A, and FIG. 10B, an input gating circuit 30 may change the input terminal based on an input control signal and change the channel for receiving the signal.

As an example, the input gating circuit 30 may select the first input terminal 31 based on a first input control signal i_cs1 and provide a signal received through the first channel ch1 to the test block 210 as an input data signal in′. Afterwards, for example, due to a change in the test path, the input gating circuit 30 may newly receive a second input control signal i_cs2. The input gating circuit 30 may change the input terminal receiving the signal from the first input terminal 31 to the second input terminal 32 based on the second input control signal i_cs2. Accordingly, a signal provided to the test block 210 as an input data signal in′ may be changed into a signal received through the second channel ch2. That is, the input data signal in′ provided to the test block 210 may be changed from a signal provided through the first channel ch1 to a signal provided through the second channel ch2.

In some embodiments, by changing the input terminals as described herein, input terminals other than the enabled second input terminal 32, which may be the activated input terminal, may be deactivated, which may enable the input gating circuit 30 to reduce toggling, where toggling may be due to unused input terminals, and reduce power consumption.

Referring to FIG. 9, FIG. 11A, and FIG. 11B, the output gating circuit 40 may change the output terminal based on the output control signal and change the channel to which the signal is to be output.

As an example, the output gating circuit 40 may select the third output terminal 43 based on a first output control signal o_cs1 and output the output data signal out' generated by the test block 210 through the third channel ch3. Afterwards, for example, due to a change in the test path, the output gating circuit 40 may newly receive a second output control signal o_cs2. The output gating circuit 40 may change the output terminal that outputs the output data signal out from the existing third output terminal 43 to the fourth output terminal 44 based on the second output control signal o_cs2. Accordingly, the channel through which the output data signal out is output may be changed from the third channel ch3 to the fourth channel ch4.

In some embodiments, by changing the output terminals as described herein, output terminals other than the enabled fourth output terminal 44, which may be the activated output terminal, may be deactivated, which may enable the output gating circuit 40 to reduce toggling, where toggling may be due to unused input terminals, and reduce power consumption.

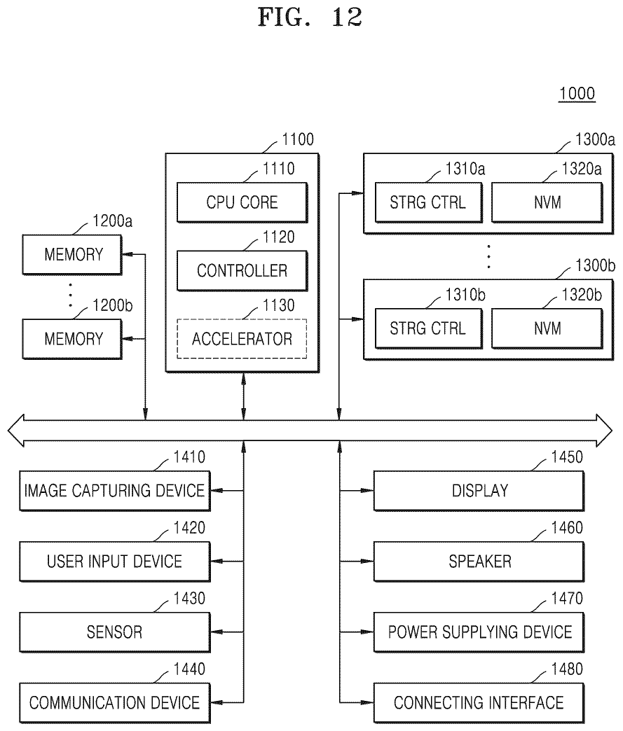

FIG. 12 illustrates a system including an integrated circuit according to an embodiment.

A system 1000 of FIG. 12 may be a mobile system, such as a mobile phone, a smartphone, a tablet personal computer (PC), a wearable device, a healthcare device, or an internet of things (IoT) device. However, the system 1000 of FIG. 12 is not limited to a mobile system, and may be a PC, a laptop computer, a server, a media player, or an automotive device such as a navigation device.

Referring to FIG. 12, the system 1000 may include a main processor 1100, memories 1200a and 1200b, and storage devices 1300a and 1300b, and may additionally include one or more of an image capturing device 1410, a user input device 1420, a sensor 1430, a communication device 1440, a display 1450, a speaker 1460, a power supplying device 1470, and a connecting interface 1480. In this case, each of the components of the system 1000 of FIG. 12, namely, the main processor 1100, the memories 1200a and 1200b, the storage devices 1300a and 1300b, the imaging capturing device 1410, the user input device 1420, the sensor 1430, the communication device 1440, the display 1450, the speaker 1460, the power supplying device 1470, and the connecting interface 1480, may be implemented using embodiments (e.g., the test circuit or integrated circuit) described herein with reference to FIGS. 1 to 11B.

The main processor 1100 may control an operation of the system 1000. In more detail, an overall operation of components of the system 1000 may be controller by the main processor 1100. The main processor 1100 may be implemented as a general-purpose processor, a dedicated processor, or an application processor.

The main processor 1100 may include one or more CPU cores 1110 and may further include a controller 1120 for controlling the memories 1200a and 1200b and/or the storage devices 1300a and 1300b. Depending on an embodiment, the main processor 1100 may further include an accelerator 1130, which may be a dedicated circuit for high-speed data operations such as artificial intelligence (AI) data operations. The accelerator 1130 may include a graphics processing unit (GPU), a neural processing unit (NPU), and/or a data processing unit (DPU), and may be implemented as a separate chip that may be physically independent from other components of the main processor 1100.

The memories 1200a and 1200b may be used as a main memory device of the system 1000. The memories 1200a and 1200b may include volatile memory such as static random-access memory (SRAM) and/or dynamic random-access memory (DRAM). The memories 1200a and 1200b may include non-volatile memory such as flash memory, phase-change random-access memory (PRAM) and/or resistive random-access memory (RRAM). The memories 1200a and 1200b may also be implemented within the same package as the main processor 1100.

The storage devices 1300a and 1300b may function as a non-volatile storage device that stores data regardless of whether power is supplied thereto, and may have a relatively large storage capacity compared to the memories 1200a and 1200b. The storage devices 1300a and 1300b may respectively include storage controllers 1310a and 1310b and non-volatile memories (NVMs) 1320a and 1320b that store data under the control of the storage controllers 1310a and 1310b. The NVMs 1320a and 1320b may include flash memory having a 2-dimensional (2D) structure or a 3-dimensional (3D) vertical NAND (V-NAND) structure. The NVMs 1320a and 1320b may include other types of nonvolatile memory such as PRAM and/or RRAM.

The storage devices 1300a and 1300b may be included in the system 1000 physically separated from the main processor 1100, or may be implemented within the same package as the main processor 1100. In addition, the storage devices 1300a and 1300b may have a form such as a solid state device (SSD) or a memory card, and may be detachably connected to other components of the system 1000 through an interface such as the connecting interface 1480. The storage devices 1300a and 1300b may be devices to which standard specifications such as universal flash storage (UFS), embedded multi-media card (eMMC) or non-volatile memory express (NVMe) are applied. Embodiments are not necessarily limited thereto.

The image capturing device 1410 may capture still images or moving images and may be a camera, a camcorder, and/or a webcam.

The user input device 1420 may receive various types of data input from a user of the system 1000, and may be a touch pad, a keyboard, a mouse, and/or a microphone.

The sensor 1430 may detect various types of physical quantities that may be obtained from outside the system 1000 and convert the detected physical quantities into electrical signals. The sensor 1430 may be a temperature sensor, a pressure sensor, a light sensor, a position sensor, an acceleration sensors, a biosensor, and/or a gyroscope sensor.

The communication device 1440 may transmit and receive signals between other devices outside the system 1000 based on various communication protocols. The communication device 1440 may be implemented including an antenna, a transceiver, and/or a modem.

The display 1450 and the speaker 1460 may function as output devices that may output visual information and auditory information, respectively, to the user of the system 1000.

The power supplying device 1470 may appropriately convert power supplied from a battery built into the system 1000 and/or an external power source and supply the converted power to each component of the system 1000.

The connecting interface 1480 may provide a connection between the system 1000 and an external device that is connected to the system 1000 and may exchange data with the system 1000. The connecting interface 1480 may be implemented in various interface methods such as advanced technology attachment (ATA), serial ATA (SATA), external SATA (e-SATA), small computer small interface (SCSI), serial attached SCSI (SAS), peripheral component interconnect (PCI), PCI express (PCIe), NVMe, IEEE 1394, universal serial bus (USB), secure digital (SD) card interface, multi-media card (MMC) interface, eMMC interface, UFS, embedded universal flash storage (eUFS), or compact flash (CF) card interface. Embodiments are not necessarily limited thereto.

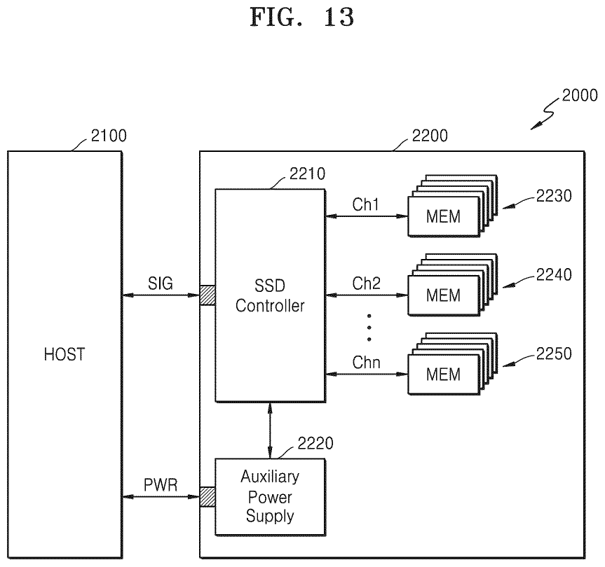

FIG. 13 is a block diagram showing an example of applying an integrated circuit according to embodiments to an SSD system.

Referring to FIG. 13, an SSD system 2000 may include a host 2100 and an SSD 2200. The SSD 2200 may exchange signals with the host 2100 through a signal connector and may receive power through a power connector. The SSD 2200 may include an SSD controller 2210, an auxiliary power supply 2220, and memory devices 2230, 2240, and 2250. The memory devices 2230, 2240, and 2250 may be vertically stacked NAND flash memory devices.

The SSD controller 2210, the auxiliary power supply 2220, and the memory devices 2230, 2240, and 2250 may include a test circuit as described herein with reference to FIGS. 1 to 11B, or may include an integrated circuit as described herein with reference to FIGS. 1 to 11B. For example, the integrated circuits included in each of the SSD controller 2210, the auxiliary power supply 2220, and the memory devices 2230, 2240, and 2250 may include a test circuit for testing one or more of the included components, and the test circuit may be implemented based on a test circuit described herein with reference to FIGS. 1 to 11B. Therefore, the test circuit may provide various test paths and test progress directions by configuring signal input/output directions in various ways, thereby supporting a flexible test structure.

While the inventive concept has been particularly shown and described with reference to embodiments thereof, it will be understood that various changes in form and details may be made therein without departing from the spirit and scope of the following claims.

What is claimed is:

1. A test circuit comprising:
a first input multiplexer configured to receive a first input data signal and a second input data signal;
a second input multiplexer configured to receive a first output signal of the first input multiplexer and a third input data signal;
a third input multiplexer configured to receive a second output signal of the second input multiplexer and a fourth input data signal;
a test block configured to generate an output data signal by performing a test operation based on an output of the third input multiplexer; and
a gating circuit configured to receive the output data signal and output the received output data signal to at least one channel.

2. The test circuit of claim 1, wherein the first input multiplexer receives a first control signal, the second input multiplexer receives a second control signal, and the third input multiplexer receives a third control signal, wherein each of the first input multiplexer, the second input multiplexer, and the third input multiplexer is configured to perform a multiplexing operation based on the first control signal, the second control signal, and the third control signal, respectively, and the first control signal, the second control signal, and the third control signal depend on an operation mode of the test circuit.

3. The test circuit of claim 1,
wherein each of the first input multiplexer, the second input multiplexer, and the third input multiplexer is configured to perform a multiplexing operation based on a control signal depending on an operation mode,
wherein, when the operation mode is a first operation mode,
the first input multiplexer outputs the first input data signal as the first output signal,
the second input multiplexer outputs the first output signal as the second output signal, and
the third input multiplexer outputs the second output signal as the output of the third input multiplexer.

4. The test circuit of claim 1,
wherein each of the first input multiplexer, the second input multiplexer, and the third input multiplexer is configured to perform a multiplexing operation based on a control signal depending on an operation mode,
wherein, when the operation mode is a second operation mode,
the first input multiplexer outputs the second input data signal as the first output signal,
the second input multiplexer outputs the first output signal as the second output signal, and
the third input multiplexer outputs the second output signal as the output of the third input multiplexer.

5. The test circuit of claim 1,
wherein each of the first input multiplexer, the second input multiplexer, and the third input multiplexer is configured to perform a multiplexing operation based on a control signal depending on an operation mode,
wherein, when the operation mode is a third operation mode,
the second input multiplexer outputs the third input data signal as the second output signal, and
the third input multiplexer outputs the second output signal as the output of the third input multiplexer.

6. The test circuit of claim 1,
wherein each of the first input multiplexer, the second input multiplexer, and the third input multiplexer is configured to perform a multiplexing operation based on a control signal depending on an operation mode, and
wherein, when the operation mode is a fourth operation mode, the third input multiplexer outputs the fourth input data signal as the output of the third input multiplexer.

7. The test circuit of claim 1, wherein the gating circuit is connected to a first channel, a second channel, a third channel, and a fourth channel, and is configured to receive the output data signal and output the received output data signal to one of the first channel to the fourth channel.

8. The test circuit of claim 7,
wherein the gating circuit further comprises
a first AND gate corresponding to the first channel and configured to receive a first enable signal, a second AND gate corresponding to the second channel and configured to receive a second enable signal, a third AND gate corresponding to the third channel and configured to receive a third enable signal, and a fourth AND gate corresponding to the fourth channel and configured to receive a fourth enable signal, and
one of the first enable signal to the fourth enable signal is activated and remaining ones of the first enable signal to the fourth enable signal are deactivated.

9. A test circuit comprising:
a first input multiplexer configured to select one of a first input data signal or a first input enable signal;
a second input multiplexer configured to select one of a second input data signal or a second input enable signal;
a third input multiplexer configured to select one of a third input data signal or a third input enable signal;
a fourth input multiplexer configured to select one of a fourth input data signal or a fourth input enable signal;
a test block configured to generate an output data signal by performing a test operation based on the selections of the first input multiplexer, the second input multiplexer, the third input multiplexer, and the fourth input multiplexer; and
a gating circuit configured to receive the output data signal and output the received output data signal to at least one channel.

10. The test circuit of claim 9, wherein each of the first input multiplexer, the second input multiplexer, the third input multiplexer, and the fourth input multiplexer is configured to perform the selection based on the first input enable signal, the second input enable signal, the third input enable signal, and the fourth input enable signal, respectively.

11. The test circuit of claim 10, wherein one of the first input enable signal to the fourth input enable signal is activated and remaining ones of the first input enable signal to the fourth input enable signal are deactivated.

12. The test circuit of claim 9, wherein the gating circuit is connected to a first channel, a second channel, a third channel, and a fourth channel, and is configured to receive the output data signal and output the received output data to one of the first channel to the fourth channel.

13. The test circuit of claim 12,
wherein the gating circuit further comprises
a first output multiplexer corresponding to the first channel;
a second output multiplexer corresponding to the second channel;
a third output multiplexer corresponding to the third channel; and
a fourth output multiplexer corresponding to the fourth channel.

14. The test circuit of claim 13, wherein the first output multiplexer is configured to gate the output data signal based on a first output enable signal, the second output multiplexer is configured to gate the output data signal based on a second output enable signal, the third output multiplexer is configured to gate the output data signal based on a third output enable signal, and the fourth output multiplexer is configured to gate the output data signal based on a fourth output enable signal.

15. The test circuit of claim 14, wherein each of the first output multiplexer to the fourth output multiplexer is configured to select a signal based on the first output enable signal to the fourth output enable signal, respectively.

16. The test circuit of claim 15, wherein one of the first output enable signal to the fourth output enable signal is activated and remaining ones of the first output enable signal to the fourth output enable signal are deactivated.

17. An integrated circuit comprising:
a plurality of channels;
at least one intellectual property (IP) block;
an input gating circuit including a plurality of input terminals including a first input terminal, each input terminal of the plurality of input terminals connected to a different channel among the plurality of channels, and configured to output a signal received through the first input terminal as an input data signal;
a test block configured to generate an output data signal by testing the at least one IP block based on the input data signal; and
an output gating circuit including a plurality of output terminals including a first output terminal, each output terminal of the plurality of output terminals connected to a different channel among the plurality of channels, and configured to output the output data signal through the first output terminal.

18. The integrated circuit of claim 17, wherein the input gating circuit receives a signal through an input terminal other than the first input terminal among the plurality of input terminals based on an input control signal.

19. The integrated circuit of claim 17, wherein the output gating circuit outputs a signal through an output terminal other than the first output terminal among the plurality of output terminals based on an output control signal.

20. The integrated circuit of claim 17,
wherein, among the plurality of input terminals, input terminals other than the first input terminal are disabled,
among the plurality of output terminals, at least one output terminal other than the first output terminal is disabled.
